(19) United States
(12) Patent Application Publication
(10) Pub. No.: US 2026/0063666 A1
(43) Pub. Date: Mar. 5, 2026

(54) FINE-PITCH PROBING SHIELD

(71) Applicant: International Business Machines Corporation, Armonk, NY (US)

(72) Inventors: Sean Teehan, Rensselaer, NY (US); Theodore M. Levin, ALBANY, NY (US); Ruturaj Nandkumar Pujari, Albany, NY (US); Arthur Roy Gasasira, Halfmoon, NY (US); David Michael Audette, Colchester, VT (US); Grant Wagner, Jericho, VT (US); Mark Christopher Johnson, Essex Junction, VT (US)

(21) Appl. No.: 18/817,393

(22) Filed: Aug. 28, 2024

(51) Int. Cl. G01R 1/067; G01R 1/073; G01R 3/00

(52) U.S. Cl. CPC G01R 1/06755; G01R 1/07342; G01R 3/00

(57) ABSTRACT

A probe assembly is provided and includes a probe card, an interposer body disposed on a surface of the probe card, probe pins arranged in a grouping and extending from the interposer body away from the probe card, each probe pin including an elongate element and a tip at a distal end of the elongate element, a mold supportable on the interposer body to fit around the grouping of the probe pins and non-conductive elastic material introduced into and cured within an interior region defined by the mold to surround at least the elongate element of each probe pin.

### BACKGROUND

The present disclosure generally relates to fine-pitch probing shields. More specifically, the present disclosure relates to a fine-pitch probing shield for electrical testing.

Wafer testing is performed during semiconductor device fabrication and generally after back-end-of-line (BEOL) processing. During wafer testing, individual integrated circuits (ICs) that are present on the wafer are tested for functional defects by applying special test patterns to them. The wafer testing is performed by a piece of test equipment called a tester, along with a wafer prober, electrically connected to the wafer via the wafer probe.

### SUMMARY

According to an aspect of the disclosure, a probe assembly is provided and includes a probe card, an interposer body disposed on a surface of the probe card, probe pins arranged in a grouping and extending from the interposer body away from the probe card, each probe pin including an elongate element and a tip at a distal end of the elongate element, a mold supportable on the interposer body to fit around the grouping of the probe pins and non-conductive elastic material introduced into and cured within an interior region defined by the mold to surround at least the elongate element of each probe pin. In accordance with one or more additional or alternative embodiments, the probe assembly adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

According to an aspect of the disclosure, a frame assembly is provided for preventing debris from entering between probe pins of a probe assembly. The frame assembly includes an adhesive frame and a non-conductive elastic material film supported on the adhesive frame. The non-conductive elastic material film defines holes arranged in accordance with an arrangement of the probe pins such that a location of each hole corresponds in location to a location of a corresponding one of the probe pins. In accordance with one or more additional or alternative embodiments, the frame assembly adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

According to an aspect of the disclosure, a probe pin insulator body is provided for creating a non-conductive barrier around probe pins of a probe assembly. The probe pin insulator body includes an insulator body of non-conductive elastic material, the insulator body including opposed major surfaces and defining openings extending between the opposed major surfaces, the openings being arranged in accordance with an arrangement of the probe pins, and, at each opening, the insulator body tightly fits around opposite ends of a corresponding one of the probe pins and includes concave surfaces that recede from sides of the corresponding one of the probe pins. In accordance with one or more additional or alternative embodiments, the probe pin insulator body adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

According to an aspect of the disclosure, a method of assembling a probe assembly in which probe pins are arranged in a grouping to extend from an interposer body and away from a probe card is provided. Each probe pin includes an elongate element and a tip at a distal end of the elongate element. The method includes supporting a mold on the interposer body to fit around the grouping of the probe pins, introducing a non-conductive elastic material in a semi-fluidic state into an interior region defined by the mold and processing the non-conductive elastic material into a solidified state within the interior region to surround at least the elongate element of each probe pin. In accordance with one or more additional or alternative embodiments, the method provides for the formation of the probe assembly and the probe assembly adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

According to an aspect of the disclosure, a method of assembling a probe assembly in which probe pins are to be arranged in a grouping to extend from an interposer body and away from a probe card is provided. Each probe pin includes an elongate element and a tip at a distal end of the elongate element. The method includes supporting a frame on the interposer body to fit around a location where the grouping of the probe pins is to be located, supportively disposing a non-conductive elastic material in the frame, forming holes in the non-conductive elastic material such that each hole corresponds in hole location to a probe pin location at which a corresponding one of the probe pins is to be located and installing the grouping of the probe pins into the location such that, at each hole, the corresponding one of the probe pins extends through the hole. In accordance with one or more additional or alternative embodiments, the method provides for the formation of the probe assembly and the probe assembly adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a side view of components of a probe assembly including first and second guide bodies in accordance with one or more embodiments;

FIG. 2 is an illustration of a formation of a probe assembly with a non-conductive elastic material and the components of FIG. 1 in accordance with one or more embodiments;

FIG. 3 is a side view of components of a probe assembly including a single interposer body in accordance with one or more embodiments;

FIG. 4 is an illustration of a formation of a probe assembly with a non-conductive elastic material and the components of FIG. 3 in accordance with one or more embodiments;

FIG. 5 is a perspective view of a frame assembly for preventing debris from entering between probe pins of a probe assembly in accordance with one or more embodiments;

FIG. 6 is a side view of a probe assembly including the frame assembly of FIG. 5 in accordance with one or more embodiments;

FIG. 7 is a perspective view of a probe pin insulator body for creating a non-conductive barrier around probe pins of a probe assembly in accordance with one or more embodiments;

FIG. 8 is a side view of the probe pin insulator body of FIG. 7 in accordance with one or more embodiments;

FIG. 9 is a flow diagram illustrating a method of assembling a probe assembly with probe pins already installed in accordance with embodiments;

FIG. 10 is a graphical flow diagram illustrating the method of FIG. 9 in accordance with one or more embodiments;

FIG. 11 is a flow diagram illustrating a method of assembling a probe assembly with probe pins to be installed in accordance with embodiments; and

FIG. 12 is a graphical flow diagram illustrating the method of FIG. 11 in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a probe assembly is provided and includes a probe card, an interposer body disposed on a surface of the probe card, probe pins arranged in a grouping and extending from the interposer body away from the probe card, each probe pin including an elongate element and a tip at a distal end of the elongate element, a mold supportable on the interposer body to fit around the grouping of the probe pins and non-conductive elastic material introduced into and cured within an interior region defined by the mold to surround at least the elongate element of each probe pin. In accordance with one or more additional or alternative embodiments, the probe assembly adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

In accordance with one or more additional or alternative embodiments, the interposer body includes a first guide body configured to abut with the surface of the probe card and a second guide body displaced from the first guide body, the probe pins extend from a surface of the first guide body facing away from the probe card in a direction that is directed away from the probe card and through the second guide body, the probe pins extend from a surface of the second guide body facing away from the probe card and the first guide body and the mold is supportable on the surface of the second guide body to support the probe pins.

In accordance with one or more additional or alternative embodiments, the non-conductive elastic material is less granular than a pitch of the probe pins and is therefore compatible with the probe assembly.

In accordance with one or more additional or alternative embodiments, the non-conductive elastic material is dispensable into and curable within the interior region and is therefore compatible with the probe assembly.

In accordance with one or more additional or alternative embodiments, the non-conductive elastic material is removable from the probe pins without losing shape and can be reused in other probe assemblies.

In accordance with one or more additional or alternative embodiments, the interposer body includes a single interposer body configured to abut with the surface of the probe card, the probe pins extend from a surface of the single interposer body facing away from the probe card in a direction that is directed away from the probe card and the mold is supportable on the surface of the single interposer body to support the probe pins.

In accordance with one or more additional or alternative embodiments, the non-conductive elastic material is sufficiently firm to prevent probe pin bending into another probe pin which avoids or reduces the risk of a short event.

In accordance with one or more additional or alternative embodiments, the non-conductive elastic material is less granular than a pitch of the probe pins and is therefore compatible with the probe assembly.

In accordance with one or more additional or alternative embodiments, the non-conductive elastic material is dispensable into and curable within the interior region and is therefore compatible with the probe assembly.

In accordance with one or more additional or alternative embodiments, the non-conductive elastic material is removable from the probe pins without losing shape and can be reused in other probe assemblies.

According to an aspect of the disclosure, a frame assembly is provided for preventing debris from entering between probe pins of a probe assembly. The frame assembly includes an adhesive frame and a non-conductive elastic material film supported on the adhesive frame. The non-conductive elastic material film defines holes arranged in accordance with an arrangement of the probe pins such that a location of each hole corresponds in location to a location of a corresponding one of the probe pins. In accordance with one or more additional or alternative embodiments, the frame assembly adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

In accordance with one or more additional or alternative embodiments, one of the probe assembly includes a probe card and an interposer body disposed on a surface of the probe card, the probe pins are arranged in a grouping and extend from the interposer body away from the probe card, each probe pin including an elongate element and a tip at a distal end of the elongate element, the interposer body includes a first guide body configured to abut with the surface of the probe card and a second guide body displaced from the first guide body, the probe pins extend from a surface of the first guide body facing away from the probe card in a direction that is directed away from the probe card and through the second guide body, the probe pins extend from a surface of the second guide body facing away from the probe card and the first guide body, and the adhesive frame is adherable to the surface of the second guide body whereby each of the probe pins extends through a corresponding one of the holes and the probe assembly includes a probe card and an interposer body disposed on a surface of the probe card, the probe pins are arranged in a grouping and extend from the interposer body away from the probe card, each probe pin including an elongate element and a tip at a distal end of the elongate element, the interposer body includes a single interposer body configured to abut with the surface of the probe card, the probe pins extend from a surface of the single interposer body facing away from the probe card in a direction that is directed away from the probe card and the adhesive frame is adherable to the surface of the single interposer body whereby each of the probe pins extends through a corresponding one of the holes to support the probe pins.

In accordance with one or more additional or alternative embodiments, the non-conductive elastic material film includes a non-conductive polymer and is therefore compatible with the frame assembly.

In accordance with one or more additional or alternative embodiments, the non-conductive elastic material film includes polyimide and is therefore compatible with the frame assembly.

In accordance with one or more additional or alternative embodiments, the non-conductive elastic material is removable from the probe pins and can be reused in other frame assemblies.

In accordance with one or more additional or alternative embodiments, the non-conductive elastic material film is sufficiently firm to prevent probe pin bending into another probe pin which avoids or reduces the risk of a short event.

According to an aspect of the disclosure, a probe pin insulator body is provided for creating a non-conductive barrier around probe pins of a probe assembly. The probe pin insulator body includes an insulator body of non-conductive elastic material, the insulator body including opposed major surfaces and defining openings extending between the opposed major surfaces, the openings being arranged in accordance with an arrangement of the probe pins, and, at each opening, the insulator body tightly fits around opposite ends of a corresponding one of the probe pins and includes concave surfaces that recede from sides of the corresponding one of the probe pins. In accordance with one or more additional or alternative embodiments, the probe pin insulator body adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

In accordance with one or more additional or alternative embodiments, one of the probe assembly includes a probe card and an interposer body disposed on a surface of the probe card, the probe pins are arranged in a grouping and extend from the interposer body away from the probe card, each probe pin including an elongate element and a tip at a distal end of the elongate element, the interposer body includes a first guide body configured to abut with the surface of the probe card and a second guide body displaced from the first guide body, the probe pins extend from a surface of the first guide body facing away from the probe card in a direction that is directed away from the probe card and through the second guide body, the probe pins extend from a surface of the second guide body facing away from the probe card and the first guide body, and the adhesive frame is adherable to the surface of the second guide body whereby each of the probe pins extends through a corresponding one of the holes and the probe assembly includes a probe card and an interposer body disposed on a surface of the probe card, the probe pins are arranged in a grouping and extend from the interposer body away from the probe card, each probe pin including an elongate element and a tip at a distal end of the elongate element, the interposer body includes a single interposer body configured to abut with the surface of the probe card, the probe pins extend from a surface of the single interposer body facing away from the probe card in a direction that is directed away from the probe card and the adhesive frame is adherable to the surface of the single interposer body whereby each of the probe pins extends through a corresponding one of the holes to support the probe pins.

In accordance with one or more additional or alternative embodiments, the non-conductive elastic material is less granular than a pitch of the probe pins and is therefore compatible with the probe pin insulator body.

In accordance with one or more additional or alternative embodiments, the non-conductive elastic material is dispensable and curable such that the openings are arranged in accordance with the arrangement of the probe pins and is therefore compatible with the probe pin insulator body.

In accordance with one or more additional or alternative embodiments, the non-conductive elastic material is removable from the probe pins without losing shape and can be reused in other probe pin insulator bodies.

According to an aspect of the disclosure, a method of assembling a probe assembly in which probe pins are arranged in a grouping to extend from an interposer body and away from a probe card is provided. Each probe pin includes an elongate element and a tip at a distal end of the elongate element. The method includes supporting a mold on the interposer body to fit around the grouping of the probe pins, introducing a non-conductive elastic material in a semi-fluidic state into an interior region defined by the mold and processing the non-conductive elastic material into a solidified state within the interior region to surround at least the elongate element of each probe pin. In accordance with one or more additional or alternative embodiments, the method provides for the formation of the probe assembly and the probe assembly adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

In accordance with one or more additional or alternative embodiments, the method further includes removing the mold and verifying that at least the tip of each probe pin is exposed from the non-conductive elastic material such that the probe pins can be electrically interacted with.

According to an aspect of the disclosure, a method of assembling a probe assembly in which probe pins are to be arranged in a grouping to extend from an interposer body and away from a probe card is provided. Each probe pin includes an elongate element and a tip at a distal end of the elongate element. The method includes supporting a frame on the interposer body to fit around a location where the grouping of the probe pins is to be located, supportively disposing a non-conductive elastic material in the frame, forming holes in the non-conductive elastic material such that each hole corresponds in hole location to a probe pin location at which a corresponding one of the probe pins is to be located and installing the grouping of the probe pins into the location such that, at each hole, the corresponding one of the probe pins extends through the hole. In accordance with one or more additional or alternative embodiments, the method provides for the formation of the probe assembly and the probe assembly adds a level of electrical isolation between probe pins to help prevent any shorting of or damage to the probe pins, prevents debris from being lodged deep between probe pins, minimizes cleaning as debris cannot get in between or around probe pins and makes cleaning easier, can retrofit existing probe technologies and can be part of newly build probe structures.

In accordance with one or more additional or alternative embodiments, the forming of the holes includes laser drilling which creates the holes but does not thermally damage the non-conductive elastic material.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, for fine-pitch and ultra-fine-pitch controlled collapse chip connection (C4) bumps, it is often critical for contacting probes and/or probe tips to be and to remain isolated from each other. This isolation serves to avoid false negative test results while measuring and/or testing C4 arrays or fine-pitch pads.

During connection operations during which probe tips are overdriven to make good contact with C4 bumps and/or pads, it is possible that the probe tips will be bent or deformed and will short out and/or contact with each other while maintaining contact with the C4 bumps and/or pads. This is typically undesirable. Also, with current probe methodologies, there is a high possibility of debris from wafers being lodged in or deposited between probes and/or needle nests. This debris can be difficult to remove without also damaging the probes themselves. The presence of the debris which cannot be easily removed can compromises electrical readouts and may also cause unnecessary shorts between probes of any pitch.

The problems of probes being bent or deformed has been previously addressed by the use of insulative coatings being applied to probe pins. Such solutions have not been found to be effective, however, and in any case do not address the problem of debris.

Turning now to an overview of the aspects of the disclosure, one or more embodiments of the disclosure address the above-described shortcomings of the prior art by providing a structure for retrofitting or assembling probes that includes a material suitable for insulating metal pins that are in close proximity to one another and prevents electrical arcing as well as debris from infiltrating areas between pins. The material may have elastic properties to allow flex in some types of probe pins. A mold can be used to facilitate the process by which the material is applied and the material can be cured in various manners such as by vibration, heat, ultraviolet (UV) light, etc. Advanced optics and evaluation software may be used to ensure the probe tips are properly exposed through the material.

The structure provides for an added level of electrical isolation between probe pins to help prevent any shorting of probe pins at fine-pitch scales and to decrease chances of damage to the probe pins and chips being tested. The structure also prevents debris from being lodged deep between pins, minimizes a need for cleaning and makes cleaning easier. The structure can be retrofit to existing probe technologies and/or can be assembled as part of newly built probes.

The above-described aspects of the disclosure address the shortcomings of the prior art by providing, for example, a probe assembly in which probe pins are arranged in a grouping and extend from an interposer body away from a probe card on which the interposer body is disposed. Each probe pin includes an elongate element and a tip at a distal end of the elongate element. The probe assembly further includes a mold supportable on the interposer body to fit around the grouping of the probe pins and non-conductive elastic material introduced into and cured within an interior region defined by the mold to surround at least the elongate element of each probe pin.

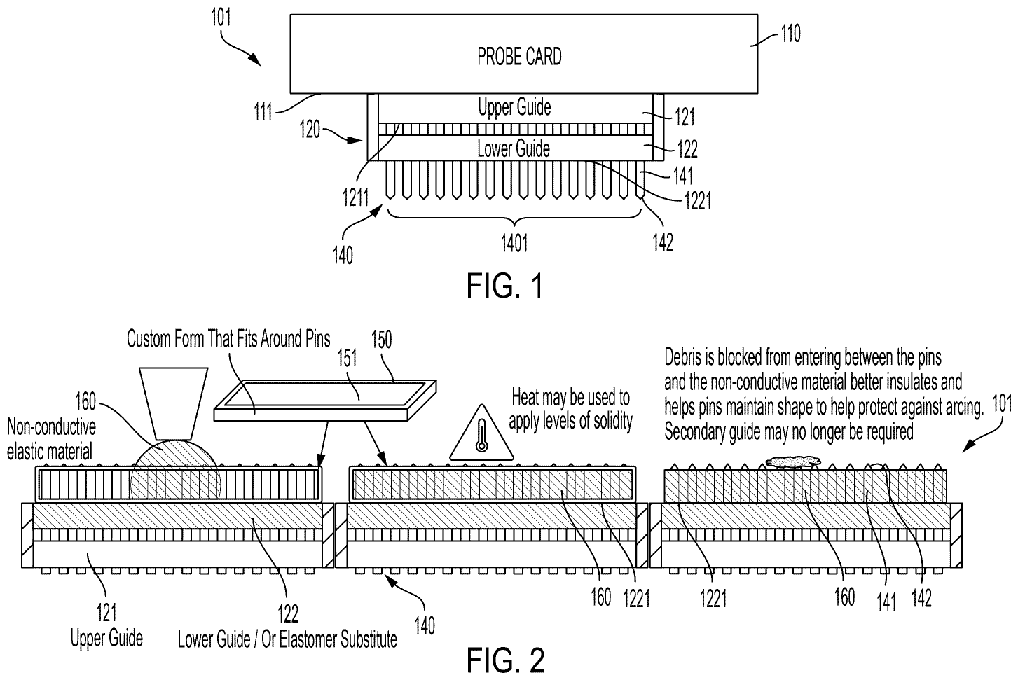

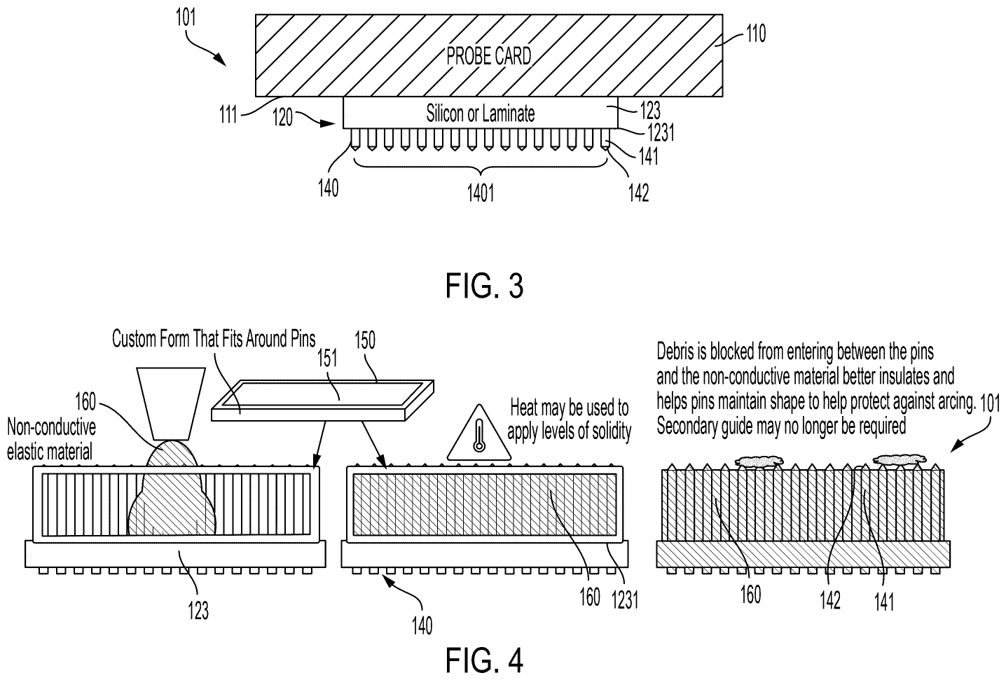

With reference to FIGS. 1 and 2 and to FIGS. 3 and 4, a probe assembly 101 is provided. The probe assembly 101 includes a probe card 110, an interposer body 120 that is disposed on a surface 111 of the probe card 110 and probe pins 140 that are arranged in a grouping 1401 and extend from the interposer body 120 away from the probe card 110. Each probe pin 140 includes an elongate element 141 and a tip 142 at a distal end of the elongate element 141. The probe assembly 101 further includes a mold 150, which is supportable on the interposer body 120 to fit around the grouping 141 of the probe pins 140, and non-conductive elastic material 160. The non-conductive elastic material 160 is introduced (i.e., by dispensing, pushing, pressing or another similar process) into and subsequently cured within an interior region 151 that is defined by the mold 150 to surround at least the elongate element 141 of each probe pin 140.

In accordance with one or more embodiments and as shown in FIGS. 1 and 2, the interposer body 120 can include a first (i.e., upper) guide body 121 configured to abut with the surface 111 of the probe card 110 and a second (i.e., lower) guide body 122 that is displaced from the first guide body 121. In these or other cases, the probe pins 140 extend from the probe card 110, through the first guide body 121 and from a surface 1211 of the first guide body 121, where the surface 1211 faces away from the probe card 110 in a direction that is directed away from the probe card 110. The probe pins 140 further extend through the second guide body 122 and from a surface 1221 of the second guide body 122, where the surface 1221 faces away from the probe card 110 and the first guide body 121. The mold 150 is supportable on the surface 1221 of the second guide body 122. The probe pins 140 can be flexible to an extent that the probe pins 140 are able to flex. Also, as will be described below, the second guide body 122 can be discarded under certain circumstances.

In accordance with one or more embodiments and as shown in FIGS. 3 and 4, the interposer body 120 can include a single interposer body 123 that is configured to abut with the surface 111 of the probe card 110. In these or other cases, the probe pins 140 extend from the single interposer body 123 and from a surface 1231 of the single interposer body 123, where the surface 1231 faces away from the probe card 110 in a direction that is directed away from the probe card 110. The mold 150 is supportable on the surface 1231 of the single interposer body 123.

The non-conductive elastic material 160 is less granular than a pitch of the probe pins 140, can be dispensable as a fluid, in a semi-fluidic state and/or as a liquid or gel into the interior region 151 and curable within the interior region 151 and can be, once cured, removable from the probe pins 140 without losing shape and reusable.

In accordance with one or more embodiments, the mold 150 can be metallic, ceramic, composite or another suitable material. The non-conductive elastic material 160 can be fluidic, liquid or gelatinous in one state so as to be introducible into the interior region 151 of the mold 150. The non-conductive elastic material 160 can be cured by thermal/drying, UV, chemical or other reactive process. Generally, the non-conductive elastic material 160 can be resistant to changes in elasticity, density and conductive properties at temperatures where utilized. Also, in general, the non-conductive elastic material 160 should have durability and resistive to chemicals used in automatic test equipment (ATE) and probers or handlers, such as conductive fluids. Furthermore, depending on usage, the non-conductive elastic material 160 must not impact measurements and signals propagated through the probe pins 140 (i.e., this includes thermal resistivity of the material, that does not increase temperature across the pins by conductivity and may in fact distribute heat away from the pins; conversely, in ultra-low temperature test environments the non-conductive elastic material 160 may be selected purposely to conduct heat to the pins to maintain optimal operating conditions).

For the one or more embodiments of FIGS. 3 and 4, since the interposer body 120 includes only the single interposer body 123, the non-conductive elastic material 160 should be sufficiently firm to prevent bending of any of the probe pins 140 into any other probe pins 140. Also, the probe pins 140 can be firm and unable to flex and, in these or other cases, the interposer body 120 can be made of relatively firm material.

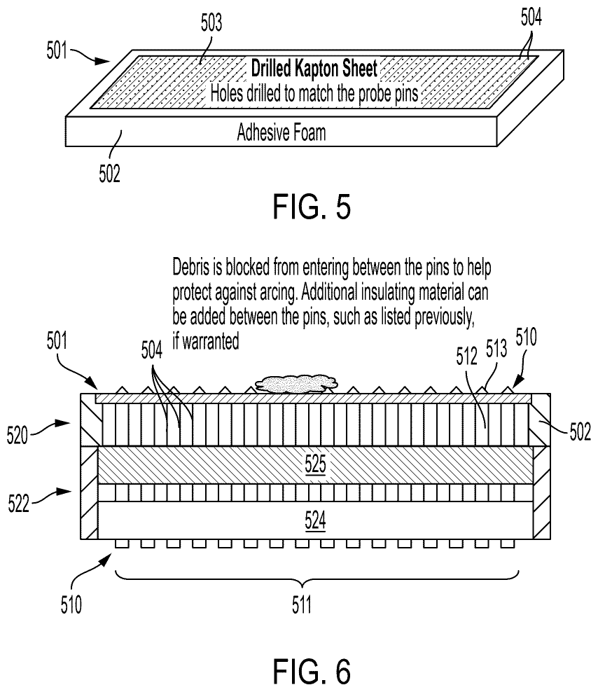

With reference to FIGS. 5 and 6, a frame assembly 501 is provided as a barrier to prevent debris from entering between probe pins 510 of a probe assembly and, in some cases as a secondary use, for supporting the probe pins 510 of the probe assembly 520.

The frame assembly 501 includes an adhesive frame 502 and a non-conductive elastic material film 503 that is supported on the adhesive frame 502. The non-conductive elastic material film 503 is formed to define holes 504 that are arranged in accordance with an arrangement of the probe pins 510. In this way, a location of each hole 504 corresponds in location to a location of a corresponding one of the probe pins 510.

In accordance with one or more embodiments and as shown in FIG. 6, the probe assembly 520 includes a probe card (see FIGS. 1 and 3) and an interposer body 522 that is disposed on a surface of the probe card. The probe pins 510 are arranged in a grouping 511 and extend from the interposer body 522 away from the probe card. Each probe pin 510 includes an elongate element 512 and a tip 513 at a distal end of the elongate element 512. The interposer body 522 can include a first guide body 524 configured to abut with the surface of the probe card and a second guide body 525 that is displaced from the first guide body 524. The probe pins 510 extend from a surface of the first guide body 524 facing away from the probe card in a direction that is directed away from the probe card and through the second guide body 525. The probe pins 510 extend from a surface of the second guide body 525 facing away from the probe card and the first guide body 524. The adhesive frame 502 is adherable to the surface of the second guide body 525 whereby each of the probe pins 510 extends through a corresponding one of the holes 504.

It is to be understood that although FIG. 6 and the accompanying text above relates to one or more embodiments, other embodiments exist. These include, but are not limited to, one or more embodiments in which the adhesive frame 502 of FIG. 5 is adherable to the single guide body 123 of FIG. 4. A detailed description of the one or more embodiments in which the adhesive frame 502 of FIG. 5 is adherable to the single guide body 123 of FIG. 4 is not necessary except to note that, where the interposer body 120 includes only the single guide body 123 as shown in FIG. 4, the non-conductive elastic material film 503 should be sufficiently firm to prevent bending of any of the probe pins 510.

The non-conductive elastic material film 503 can be provided as a non-conductive polymer, such as polyimide (e.g., Kapton ™), and can be removable from the probe pins 510 and reusable. In general, the non-conductive elastic material film 503 can be durable, flexible, non-conductive and resistant to extreme temperatures. More particularly, the non-conductive elastic material film should be sufficiently firm to prevent bending of any of the probe pins 510. Furthermore, depending on usage, the non-conductive elastic material film 503 must not impact measurements and signals propagated through the probe pins 510 (i.e., this includes thermal resistivity of the material, that does not increase temperature across the pins by conductivity and may in fact distribute heat away from the pins; conversely, in ultra-low temperature test environments the non-conductive elastic material film 503 may be selected purposely to conduct heat to the probe pins 510 to maintain optimal operating conditions).

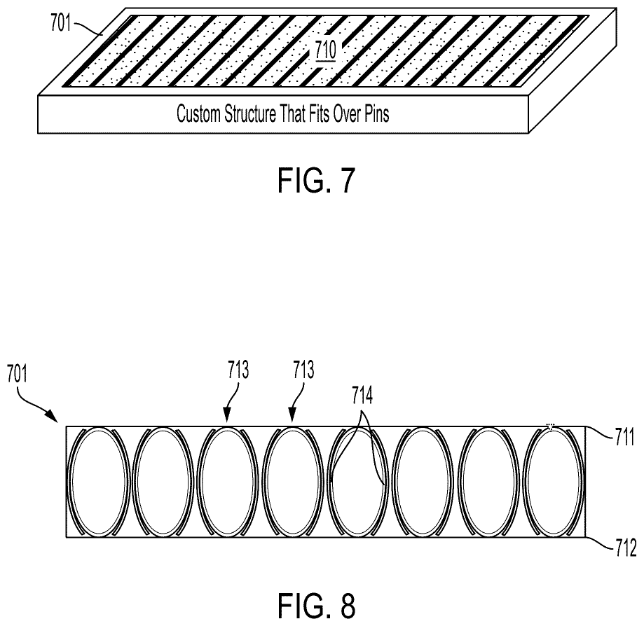

With reference to FIGS. 7 and 8, a probe pin insulator body 701 is provided for creating a non-conductive barrier around probe pins of a probe assembly, such as the probe assembly 101 and the probe pins 140 of FIGS. 1 and 2 and FIGS. 3 and 4 and, in some cases as a secondary use, for supporting the probe pins of the probe assembly. In any case, the probe pin insulator body 701 includes a insulator body 710 of non-conductive elastic material, which can be similar to the non-conductive elastic material of FIGS. 1 and 2 and FIGS. 3 and 4 but which should also be specialized for molding into specific shapes. The insulator body 710 includes opposed major surfaces 711, 712 and is formed to define openings 713 extending between the opposed major surfaces 711, 712. The openings 713 are arranged in accordance with an arrangement of the probe pins 702. At each opening 713, the insulator body 710 tightly fits around opposite ends of a corresponding one of the probe pins 702 and includes concave surfaces 714 that recede from sides of the corresponding one of the probe pins 702.

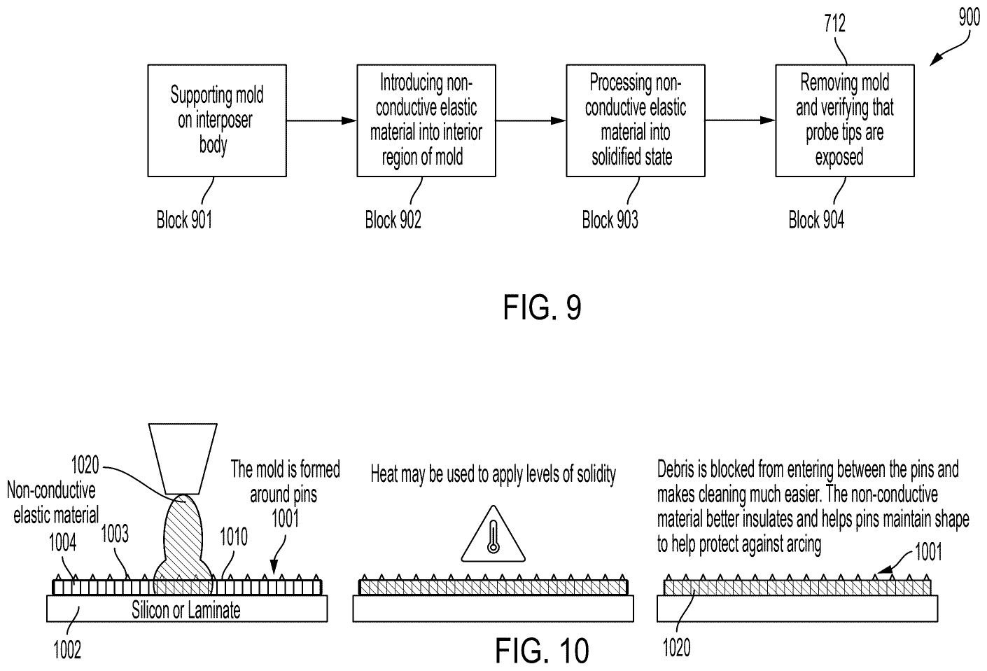

With continued reference to FIGS. 1-4 and with additional reference to FIGS. 9 and 10, a method 900 of assembling a probe assembly in which probe pins 1001 are arranged in a grouping to extend from an interposer body 1002 and away from a probe card, each probe pin 1001 including an elongate element 1003 and a tip 1004 at a distal end of the elongate element 1003. As shown in FIG. 9 and as illustrated in FIG. 10, the method 900 includes supporting a mold 1010 on the interposer body 1002 to fit around the grouping of the probe pins 1001 (block 901 of FIG. 9), introducing a non-conductive elastic material 1020 in a semi-fluidic state (i.e., elastic insulator in a malleable form, such as a heavy liquid, gel or paste) into an interior region defined by the mold 1010 (block 902 of FIG. 9), processing the non-conductive elastic material 1020 into a solidified state by, for example, vibration, heating, UV curing, etc., within the interior region to surround at least the elongate element 1003 of each probe pin 1001 (block 903 of FIG. 9) and, optionally, removing the mold 1010 and verifying that at least the tip 1004 of each probe pin 1001 is exposed from the non-conductive elastic material 1020 (block 904 of FIG. 9).

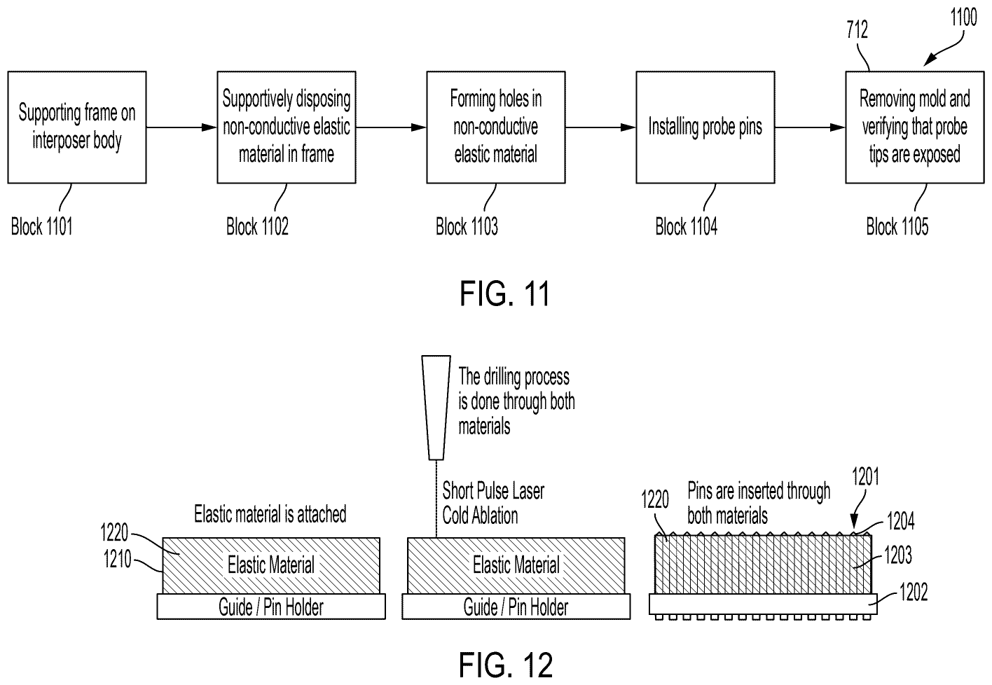

With continued reference to FIGS. 5-8 and with additional reference to FIGS. 11 and 12, a method 1100 of assembling a probe assembly in which probe pins 1201 are to be arranged in a grouping to extend from an interposer body 1202 and away from a probe card, each probe pin 1201 including an elongate element 1203 and a tip 1204 at a distal end of the elongate element 1203. A shown in FIG. 11 and as illustrated in FIG. 12, the method 1100 includes supporting a frame 1210 on the interposer body 1202 to fit around a location where the grouping of the probe pins 1201 is to be located (block 1101 of FIG. 11), supportively disposing a non-conductive elastic material 1220 in the frame 1210 (block 1102 of FIG. 11), forming holes by, for example, drilling, laser drilling, etc., in the non-conductive elastic material 1220 such that each hole corresponds in hole location to a probe pin location at which a corresponding one of the probe pins 1201 is to be located (block 1103 of FIG. 11), installing the grouping of the probe pins 1201 into the location such that, at each hole, the corresponding one of the probe pins 1201 extends through the hole (block 1104 of FIG. 11) and, optionally, removing the frame 1210 and verifying that at least the tip 1004 of each probe pin 1001 is exposed from the non-conductive elastic material 1220 (block 1105 of FIG. 11). It is to be understood that, where the holes are formed by laser drilling, for example, the non-conductive elastic material 1220 should be resistance to heat damage by the laser.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect.

Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration. ” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc.

The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about”can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A probe assembly, comprising:
a probe card;
an interposer body disposed on a surface of the probe card;
probe pins arranged in a grouping and extending from the interposer body away from the probe card, each probe pin comprising an elongate element and a tip at a distal end of the elongate element;
a mold supportable on the interposer body to fit around the grouping of the probe pins; and
non-conductive elastic material introduced into and cured within an interior region defined by the mold to surround at least the elongate element of each probe pin.

2. The probe assembly according to claim 1, wherein:
the interposer body comprises a first guide body configured to abut with the surface of the probe card and a second guide body displaced from the first guide body,
the probe pins extend from a surface of the first guide body facing away from the probe card in a direction that is directed away from the probe card and through the second guide body,
the probe pins extend from a surface of the second guide body facing away from the probe card and the first guide body, and
the mold is supportable on the surface of the second guide body.

3. The probe assembly according to claim 1, wherein the non-conductive elastic material is less granular than a pitch of the probe pins.

4. The probe assembly according to claim 1, wherein the non-conductive elastic material is dispensable into and curable within the interior region.

5. The probe assembly according to claim 1, wherein the non-conductive elastic material is removable from the probe pins without losing shape.

6. The probe assembly according to claim 1, wherein:
the interposer body comprises a single interposer body configured to abut with the surface of the probe card,
the probe pins extend from a surface of the single interposer body facing away from the probe card in a direction that is directed away from the probe card, and
the mold is supportable on the surface of the single interposer body.

7. The probe assembly according to claim 6, wherein the non-conductive elastic material is sufficiently firm to prevent probe pin bending into another probe pin.

8. The probe assembly according to claim 1, wherein the non-conductive elastic material is less granular than a pitch of the probe pins.

9. The probe assembly according to claim 1, wherein the non-conductive elastic material is dispensable into and curable within the interior region.

10. The probe assembly according to claim 1, wherein the non-conductive elastic material is removable from the probe pins without losing shape.

11. A frame assembly for preventing debris from entering between probe pins of a probe assembly, the frame assembly comprising:
an adhesive frame; and
a non-conductive elastic material film supported on the adhesive frame,
the non-conductive elastic material film defines holes arranged in accordance with an arrangement of the probe pins such that a location of each hole corresponds in location to a location of a corresponding one of the probe pins.

12. The frame assembly according to claim 11, wherein one of:
the probe assembly comprises a probe card and an interposer body disposed on a surface of the probe card, the probe pins are arranged in a grouping and extend from the interposer body away from the probe card, each probe pin comprising an elongate element and a tip at a distal end of the elongate element, the interposer body comprises a first guide body configured to abut with the surface of the probe card and a second guide body displaced from the first guide body, the probe pins extend from a surface of the first guide body facing away from the probe card in a direction that is directed away from the probe card and through the second guide body, the probe pins extend from a surface of the second guide body facing away from the probe card and the first guide body, and the adhesive frame is adherable to the surface of the second guide body whereby each of the probe pins extends through a corresponding one of the holes, and
the probe assembly comprises a probe card and an interposer body disposed on a surface of the probe card, the probe pins are arranged in a grouping and extend from the interposer body away from the probe card, each probe pin comprising an elongate element and a tip at a distal end of the elongate element, the interposer body comprises a single interposer body configured to abut with the surface of the probe card, the probe pins extend from a surface of the single interposer body facing away from the probe card in a direction that is directed away from the probe card and the adhesive frame is adherable to the surface of the single interposer body whereby each of the probe pins extends through a corresponding one of the holes.

13. The frame assembly according to claim 11, wherein the non-conductive elastic material film comprises a non-conductive polymer.

14. The frame assembly according to claim 11, wherein the non-conductive elastic material film comprises polyimide.

15. The frame assembly according to claim 11, wherein the non-conductive elastic material is removable from the probe pins.

16. The frame assembly according to claim 11, wherein the non-conductive elastic material film is sufficiently firm to prevent probe pin bending into another probe pin.

17. A probe pin insulator body for creating a non-conductive barrier around probe pins of a probe assembly, the probe pin insulator body comprising:
an insulator body of non-conductive elastic material,
the insulator body comprising opposed major surfaces and defining openings extending between the opposed major surfaces,
the openings being arranged in accordance with an arrangement of the probe pins, and,
at each opening, the insulator body tightly fits around opposite ends of a corresponding one of the probe pins and comprises concave surfaces that recede from sides of the corresponding one of the probe pins.

18. The probe pin insulator body according to claim 17, wherein one of:
the probe assembly comprises a probe card and an interposer body disposed on a surface of the probe card, the probe pins are arranged in a grouping and extend from the interposer body away from the probe card, each probe pin comprising an elongate element and a tip at a distal end of the elongate element, the interposer body comprises a first guide body configured to abut with the surface of the probe card and a second guide body displaced from the first guide body, the probe pins extend from a surface of the first guide body facing away from the probe card in a direction that is directed away from the probe card and through the second guide body, the probe pins extend from a surface of the second guide body facing away from the probe card and the first guide body, and the support body is supportable on the surface of the second guide body, and
the probe assembly comprises a probe card and an interposer body disposed on a surface of the probe card, the probe pins are arranged in a grouping and extend from the interposer body away from the probe card, each probe pin comprising an elongate element and a tip at a distal end of the elongate element, the interposer body comprises a single interposer body body configured to abut with the surface of the probe card, the probe pins extend from a surface of the single interposer body facing away from the probe card in a direction that is directed away from the probe card and the support body is supportable on the surface of the single interposer body.

19. The probe pin insulator body according to claim 17, wherein the non-conductive elastic material is less granular than a pitch of the probe pins.

20. The probe pin insulator body according to claim 17, wherein the non-conductive elastic material is dispensable and curable such that the openings are arranged in accordance with the arrangement of the probe pins.

21. The probe pin insulator body according to claim 17, wherein the non-conductive elastic material is removable from the probe pins without losing shape.

22. A method of assembling a probe assembly in which probe pins are arranged in a grouping to extend from an interposer body and away from a probe card, each probe pin comprising an elongate element and a tip at a distal end of the elongate element, the method comprising:
supporting a mold on the interposer body to fit around the grouping of the probe pins;
introducing a non-conductive elastic material in a semi-fluidic state into an interior region defined by the mold; and
processing the non-conductive elastic material into a solidified state within the interior region to surround at least the elongate element of each probe pin.

23. The method according to claim 22, further comprising removing the mold and verifying that at least the tip of each probe pin is exposed from the non-conductive elastic material.

24. A method of assembling a probe assembly in which probe pins are to be arranged in a grouping to extend from an interposer body and away from a probe card, each probe pin comprising an elongate element and a tip at a distal end of the elongate element, the method comprising:
supporting a frame on the interposer body to fit around a location where the grouping of the probe pins is to be located;
supportively disposing a non-conductive elastic material in the frame;
forming holes in the non-conductive elastic material such that each hole corresponds in hole location to a probe pin location at which a corresponding one of the probe pins is to be located; and
installing the grouping of the probe pins into the location such that, at each hole, the corresponding one of the probe pins extends through the hole.

25. The method according to claim 24, wherein the forming of the holes comprises laser drilling.
